(19) United States
(12) Patent Application Publication
(10) Pub. No.: US 2026/0366141 A1
(43) Pub. Date: Nov. 19, 2026

(54) FLUORINE REDUCTION IS SILICON-CONTAINING FILMS

(71) Applicant: Lam Research Corporation, Fremont, CA (US)

(72) Inventors: Ian John Curtin, Portland, OR (US); Pulkit Agarwal, Beaverton, OR (US); Tao Zhang, Tigard, OR (US); Mamoru Imade, Sherwood, OR (US); Shiva Sharan Bhandari, Sherwood, OR (US); Douglas Walter Agnew, Portland, OR (US)

(73) Assignee: Lam Research Corporation, Fremont, CA (US)

(21) Appl. No.: 19/124,214

(22) PCT Filed: Oct. 20, 2023
(86) PCT No.: PCT/US2023/077404

§ 371 Date: Apr. 24, 2025

Related U.S. Application Data
(60) Provisional application No. 63/380,729, filed on Oct. 24, 2022.

(51) Int. Cl. C23C 16/04; C23C 16/40; C23C 16/455; C23C 16/505; C23C 16/56; H01J 37/32; H10P 14/60; H10P 14/692

(52) U.S. Cl. CPC C23C 16/045; C23C 16/401; C23C 16/45536; C23C 16/45544; C23C 16/505; C23C 16/56; H10P 14/6336; H10P 14/6339; H10P 14/6514; H10P 14/69215; H01J 37/32082; H01J 2237/33

(57) ABSTRACT

Methods of filling a gap with a dielectric material including using an inhibition plasma during deposition. The inhibition plasma increases a nucleation barrier of the deposited film. A passivation plasma may remove inhibitor species adsorbed on the surface or in the bulk of a deposited dielectric material.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes.

### BACKGROUND

Many semiconductor device fabrication processes involve formation of films including silicon-containing films such as silicon oxide or silicon nitride. Plasma enhanced atomic layer deposition (PEALD) may be used to deposit silicon-containing films. Depositing a high-quality film can be particularly challenging when depositing films in gaps. Inhibitor species may be used as part of depositing films in gaps.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Disclosed herein are methods and systems of depositing dielectric material. In one aspect of the embodiments herein a method is provided, the method including: providing a substrate in a process chamber, the substrate having one or more structures, each structure including a gap; performing a first set of cycles of: (a) exposing the substrate to an inhibition plasma to inhibit deposition on a portion of each gap, wherein the inhibition plasma includes fluorine-containing species, and (b) after (a), depositing a dielectric material in each gap, and after performing the first set of cycles, exposing the substrate to a passivation plasma to reduce a concentration of fluorine in the dielectric material, wherein the concentration of fluorine after exposing the substrate to the passivation plasma is less than about 10²⁰ atoms/cm³. In some embodiments, the concentration of fluorine in the dielectric material is measured from a bulk portion of the dielectric material. In some embodiments, the concentration of fluorine in the dielectric material is an average concentration at a depth from a surface of the substrate of at least 5 nm. In some embodiments, the concentration of fluorine after exposing the substrate to the passivation plasma is less than about 10¹⁹ atoms/cm³. In some embodiments, a duration of the passivation plasma is at least about 80 seconds. In some embodiments, the passivation plasma has a high frequency (HF) power of at least about 5000 W. In some embodiments, the passivation plasma has a low frequency (LF) power between about 0 and about 2000 W. In some embodiments, the dielectric material has a wet etch rate less than 1 A/s. In some embodiments, the inhibition plasma includes a nitrogen-containing species. In some embodiments, the passivation plasma reduces the concentration of nitrogen in the dielectric material. In some embodiments, the dielectric material includes silicon-containing material. In some embodiments, the silicon-containing material includes silicon oxide. In some embodiments, the passivation plasma includes an oxygen-containing species. In some embodiments, the passivation plasma includes a hydrogen-containing species. In some embodiments, the passivation plasma includes an oxygen-containing species and a hydrogen-containing species.

In another aspect of the embodiments herein, a system is provided, the system including: a process chamber; and one or more processors and one or more memories, the one or more processors and the one or more memories including computer-executable instructions for: providing a substrate in the process chamber, the substrate having one or more structures, each structure including a gap; performing a first set of cycles of: exposing the substrate to an inhibition plasma to inhibit deposition on a portion of each gap, wherein the inhibition plasma includes fluorine-containing species, and after (a), depositing a dielectric material in each gap, and after performing the first set of cycles, exposing the substrate to a passivation plasma, wherein a duration of the passivation plasma is at least about 80 seconds and a high frequency (HF) power of the passivation plasma is at least about 5000 W.

These and other features of the disclosed embodiments will be described in detail below with reference to the associated drawings.

### BRIEF DESCRIPTION OF DRAWINGS

FIG. 1 presents a flow diagram of operations for one example embodiment.

FIG. 2 presents a chart of fluorine concentration as a function of depth for various deposition processes.

FIG. 3 presents a flow diagram of operations for one example embodiment.

FIG. 4 presents a flow diagram of operations for atomic layer deposition processes.

FIGS. 5-8 are schematic diagrams of examples of process chambers for performing methods in accordance with disclosed embodiments.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes often include dielectric gap fill using chemical vapor deposition (CVD) and/or atomic layer deposition (ALD) methods to fill features. Described herein are methods of filling features with dielectric material including but not limited to silicon-containing films such as silicon oxide, and related systems and apparatuses. The methods described herein can be used to fill vertically oriented features formed in a substrate. Such features may be referred to as gaps, recessed features, negative features, unfilled features, or simply features. Filling such features may be referred to as gapfill. Features formed in a substrate can be characterized by one or more of narrow and/or re-entrant openings, constrictions within the feature, and high aspect ratios. In some implementations, a feature may have an aspect ratio of at least about 2:1, at least about 4:1, at least about 6:1, at least about 20:1, at least about 100:1, or greater. The substrate may be a silicon or other semiconductor wafer, e.g., a 200-mm wafer, a 300-mm wafer, or a 450-mm wafer, including wafers having one or more layers of material such as dielectric, conducting, or semi-conducting material deposited thereon.

One aspect of the disclosure relates to a method of using an inhibition plasma during atomic layer deposition (ALD) of dielectric material in gaps that facilitates void-free bottom-up gapfill. The inhibition plasma creates a passivated surface and increases a nucleation barrier of the deposited ALD film. When the inhibition plasma interacts with material in the feature, the material at the bottom of the feature receives less plasma treatment than material located closer to a top portion of the feature or on the field region surrounding the feature because of geometrical shadowing effects. As a result, deposition at the top of the feature is selectively inhibited and deposition in lower portions of the feature proceeds with less inhibition or without being inhibited. As a result, bottom-up fill is enabled in an ALD process, which creates a more favorable sloped profile that mitigates seam effect and prevents void formation. Halogen-containing plasmas can be effective inhibition plasmas. For example, for some applications, a plasma generated from nitrogen trifluoride (NF₃) may provide an inhibition effect in a substantially reduced time compared to a plasma generated from molecular nitrogen (N₂).

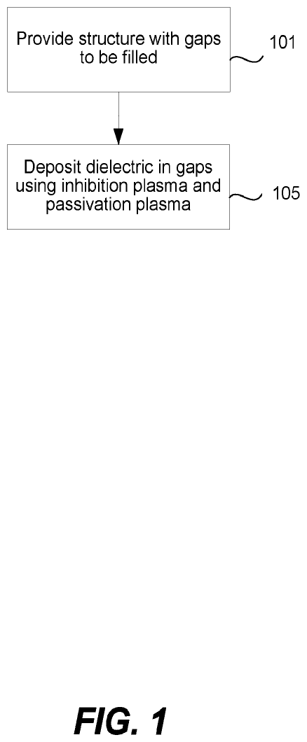

FIG. 1 is a process flow diagram that illustrates a method of filling gaps with dielectric material. The method begins with providing a structure with one or more gaps to be filled. (101). The structure may be formed by one or more layers of material deposited on a substrate. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods may also be applied to for gapfill other substrates, such as glass, plastic, and the like, including in the fabrication of microelectromechanical (MEMS) devices.

Examples of structures include 3D NAND structures, DRAM structures, and shallow trench isolation (STI) structures. The structures include gaps with the sidewalls of the gaps formed by a material susceptible to etch. In one example, 3D NAND structure includes oxide-nitride-oxide-nitride (ONON) stacks covered with a poly Si layer. In another example, structures may include lateral/tunnel structures that extend horizontally from a common vertical trench. Other examples of sidewall materials include oxides, metals, and semiconducting materials. The methods described herein are not limited to a particular class of sidewall material and may be used to inhibit any susceptible material.

Dielectric material is deposited in the gaps using an inhibition plasma and a passivation plasma. (105). As discussed further below, this can involve cycles of inhibition plasma followed by cycles of ALD of the dielectric material. The inhibition plasma treatment may result in the adsorption of inhibitor species, in particular halogen species such as fluorine as well as nitrogen when, e.g., NF₃ is used as an inhibitor species. While fluorine is discussed throughout the application, in some embodiments a different halogen species may be used as an inhibitor with the processes described herein. The adsorbed inhibitor species may then block precursor species from adsorbing, inhibiting an atomic layer deposition (ALD) process of dielectric material. A passivation plasma may then be used to remove inhibitor species.

An inhibition plasma treatment may be characterized by an inhibition effective depth (IED). The IED describes a depth above which deposition will be inhibited. During design of a bottom-up fill process, multiple inhibition blocks may be planned where an inhibition plasma treatment may be changed between inhibition blocks. For example, an inhibition plasma treatment may be tuned so that the IED is closer to the bottom of the feature, e.g., 75% of the total depth of the feature is inhibited. Cycles of an ALD process may then be performed to fill the bottom 25% of the feature. The inhibition plasma parameters may then be adjusted to inhibit, e.g., the top 50% of the feature (relative to the total depth and notwithstanding any fill), and then the next bottom portion of the feature is filled.

In some embodiments the passivation plasma is used to remove inhibitor species prior to changing the inhibition plasma properties to change how the surface is inhibited. For example, a passivation plasma may be used between inhibition blocks to remove any inhibitor species that may remain below a desired IED for a subsequent inhibition block. This helps increase the deposition rate of dielectric material as well as reduce the incorporation of fluorine into the deposited dielectric material.

In some embodiments, a passivation plasma may be a hydrogen plasma and/or an oxygen plasma. In some embodiments, the hydrogen plasma reacts with adsorbed fluorine to form HF gas that may then be evacuated from a process chamber (a hydrogen plasma may also be used with many halogen inhibitor species to form HX, where X is a halogen). Similarly, an oxygen plasma may react with adsorbed nitrogen to form NO and/or NO₂ gas that may then be evacuated from the process chamber.

While a hydrogen and/or oxygen plasma is effective to remove surface adsorbed fluorine and/or nitrogen, in some embodiments, fluorine and/or nitrogen species may diffuse into the film. This diffusion may occur between the inhibition plasma treatment that results in the adsorption of inhibitor species and a passivation treatment to remove adsorbed inhibitor species. The increased concentration of fluorine and/or nitrogen in the film is undesirable.

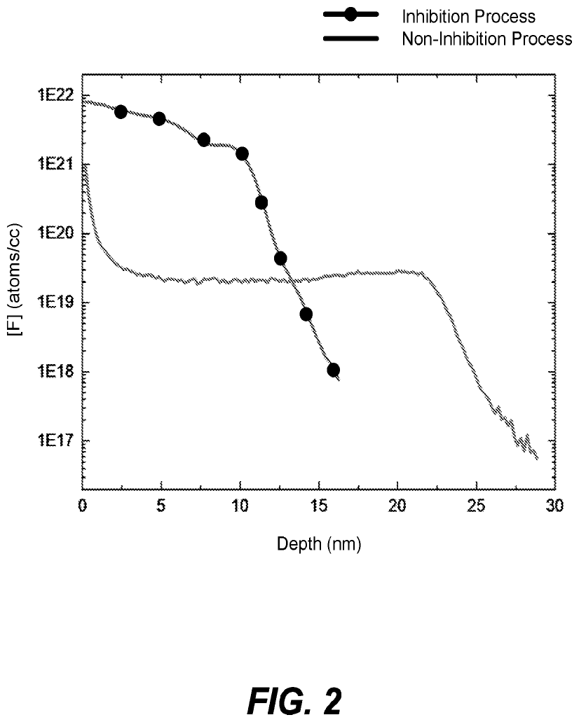

FIG. 2 presents a graph of fluorine concentration as a function of depth for an inhibition process and a non-inhibition process based on a secondary ion mass spectrometry analysis (SIMS). The inhibition process uses an inhibition plasma (using NF₃ to generate the plasma) and passivation plasma (using O₂ and H₂ to generate the plasma) treatment as described herein, while the non-inhibition process does not use an inhibition plasma or a passivation plasma. In particular, the passivation plasma was performed at a pressure of 2 Torr, a HF power of 1250 W, and for a duration of 40 seconds. As shown in FIG. 2, the inhibition process has a much higher fluorine concentration than the non-inhibition process. The concentration of fluorine in the non-inhibition process film was about 3.9×10¹⁹ atoms/cm³, while the concentration of fluorine in the inhibition process film is about 4.2×10²¹ atoms/cm³. In some embodiments, concentration may be an average concentration measured in a bulk portion of a film. The bulk portion may be a portion of a semiconductor material that has uniform properties throughout the whole piece, as measured in those parts of the piece in which the measured value of a characteristic is not modified by the proximity of the boundaries of the piece. For example, in FIG. 2 the concentration of the non-inhibition process may be measured at a depth greater than about 5 nm. Below 5 nm the fluorine concentration may vary with depth, however at a depth greater than 5 nm the concentration may be relatively stable until another boundary layer shown at about 20 nm (for the non-inhibition process film).

The concentration difference may be caused by the diffusion of adsorbed fluorine from the inhibition plasma into the film as the non-inhibition process would not have another source of fluorine species to be incorporated into the film, (In some embodiments a chamber clean process may include fluorine-containing species that can be incorporated into films as contaminants, however both processes would be subject to such fluorine contaminants). Notably, while a passivation plasma process may be performed to remove fluorine, in the inhibition process shown in FIG. 2 it is insufficient to remove fluorine from the bulk film. The inhibition process shown in FIG. 2 may be sufficient for a bottom-up fill process to proceed, but the passivation plasma does not remove fluorine that diffused into the film from exposure to an inhibition plasma.

It should be noted that the processes shown in FIG. 2 were each performed for the same number of cycles. An inhibition process typically has a slower film growth per cycle than a non-inhibition process, such that the depth shown in FIG. 2 is not calibrated between the two shown processes. The two processes were each performed for the same number of cycles, resulting in a thinner deposited film from the inhibition process and thus a translated/compressed curve of fluorine concentration as a function of depth for the inhibition process compared to the non-inhibition process. The curves of fluorine concentration are presented for qualitative illustration and concentrations may vary based on differences in film deposition and measurement technique.

To remove fluorine from the bulk film, a passivation process may be tuned to reduce fluorine concentration in the bulk film as well as remove fluorine from a surface of a substrate. In some embodiments, a high power, long duration, or high hydrogen/oxygen gas flow passivation may be performed to reduce fluorine concentration in the film. In some embodiments, a high power passivation may have a plasma power having a low frequency (LF) and high frequency (HF) component, wherein the LF power may be between about 0 and about 5000 W and the HF power may be between about 1250 and about 6000 W. In some embodiments, a higher HF power and a lower LF power may be favorable as the LF power may increase a sputtering effect of the plasma on the deposited film, which is undesirable. Generally, a higher RF power may increase the energy of species and drive reaction kinetics towards forming HF that may then be evacuated from a process chamber.

In some embodiments, a long duration passivation process may also be used. For example, a passivation process may be at least about 40 seconds, at least about 60 seconds, at least about 80 seconds, at least about 100 seconds, at least about 120 seconds, or between about 40 seconds and about 120 seconds or between about 60 seconds and about 120 seconds. In some embodiments, a longer duration passivation plasma process may remove fluorine at the surface, causing a concentration gradient that allows additional fluorine to diffuse to the surface, react, and evacuate throughout the duration of the passivation plasma.

In some embodiments, the gas flow of hydrogen-containing or oxygen-containing species may be increased. While H₂ and O₂ are typically used as hydrogen-containing or oxygen-containing species, respectively, in some embodiments other hydrogen-containing or oxygen-containing species may be used. As the hydrogen and oxygen may react with halogen/nitrogen species to form gaseous species that may be evacuated, a higher partial pressure of such species may improve the reaction kinetics and further reduce halogen/nitrogen impurities. In some embodiments, an inert gas may also be co-flowed, where the inert gas may be, e.g., helium or argon. In some embodiments, an inert gas may not be co-flowed to further increase the partial pressure of hydrogen- and oxygen-containing species.

In some embodiments, the flow of hydrogen-containing species may be at least about 2000 sccm or between about 2000 sccm and about 5000 sccm, while the flow of oxygen-containing species may be between about 0 sccm and about 5000 sccm.

In some embodiments the pressure may also be increased to reduce sputtering of the film. In some embodiments, the pressure of a passivation process may be between about 2 Torr and about 12 Torr.

Table 1 below summarizes two passivation processes that may be used to reduce fluorine (or other halogen) concentrations. The base process is the process used for the inhibition process illustrated in FIG. 2. In some embodiments, a passivation process as described herein may reduce fluorine concentration to less than about than 10²⁰ atoms/cm³, less than about 10¹⁹ atoms/cm³, less than about 10¹⁸ atoms/cm³, or between about 10²⁰ and about 10¹⁸ atoms/cm³. It should be understood that the parameters below are example processes and a range of parameters may be used as described herein.

TABLE 1

| | | HF | LF | | | | | |
|---|---|---|---|---|---|---|---|---|
| Passivation | Pressure | PWR | PWR | Gas Flow (sccm) | | | Passivation | Average [F] |
| Split | (T) | (W) | (W) | H₂ | O₂ | Ar | Time (sec) | concentration |
| Base | 2 | 1250 | 0 | 2000 | 2000 | 2400 | 40 | 4.2E21 |
| High HF | 6 | 6000 | 0 | 3000 | 5000 | 12400 | 120 | 3.7E19 |
| passivation | | | | | | | | |
| HF/LF | 6 | 3000 | 2000 | 3000 | 5000 | 12400 | 120 | 5.6E19 |
| passivation | | | | | | | | |

In some embodiments, a high power/long duration passivation process as described herein may also improve other material properties of deposited films in addition to reducing fluorine impurities. Table 2 below shows material properties of a film deposited using an inhibition plasma and passivation plasma process as described herein, as well as plasma-enhanced ALD processes that do not use an inhibition or passivation plasma. The 5000 W ALD film generally has better material properties than a 1250 W ALD film, e.g., lower wet etch rate (WER) and wet etch rate ratio (WERR). Notably, a high HF passivation process (which includes a passivation plasma process as described in table 1 above) has similar properties to the 5000 W ALD film. Notably, the ALD portion of the high HF passivation deposition process has similar deposition parameters as the 1250 W ALD film in Table 2, but the high HF passivation plasma improves the film properties to be closer to the 5000 W ALD film.

Thus, in some embodiments, a passivation process as described herein may reduce the concentration of fluorine in the film as well as improve the WER, WERR, refractive index (RI), and other material properties. In some embodiments, a WER of dielectric material deposited using a passivation process as described herein may be less than about 1 A/s.

TABLE 2

| | Thick- | | | | | E_{BD} | Jₗₑₐₖ@- |
|---|---|---|---|---|---|---|---|
| | ness | WER | | | | (MV/ | 2 MV/cm |
| Process | (Å) | (A/s) | WERR | RI | ϵᵣ | cm) | (A/cm²) |
| High HF | 803 | 0.7 | 1.6 | 1.46 | 4.0 | 9.8 | 4.8E−10 |
| passivation | | | | | | | |
| 1250 W | 938 | 1.3 | 2.9 | 1.45 | 4.3 | 11.1 | 9.8E−10 |
| ALD | | | | | | | |
| 5000 W | 750 | 0.7 | 1.5 | 1.46 | 4.0 | 9.8 | 2.8E−10 |
| ALD | | | | | | | |

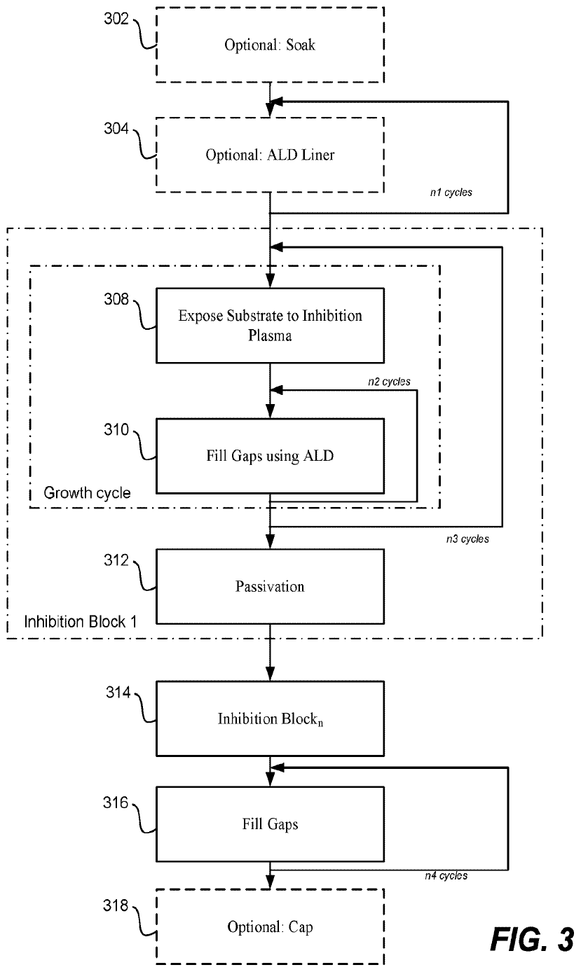

FIG. 3 shows an example of a process sequence that may be used in accordance with the disclosed embodiments. The process sequence in FIG. 3 includes treating a substrate with an inhibition plasma. Other operations (e.g., soak) may be omitted in certain embodiments and operations may be added in certain embodiments. In the example process sequence of FIG. 3, one or more wafers undergo gap fill. The process may begin with a soak after being provided to a deposition chamber. (302). This can be useful, for example, to remove particles or other pretreatment. Then, n1 cycles of ALD deposition of a liner are performed. (304). If deposited, the liner is a material that protects the underlying structure from plasma damage. It may be the same or different material as the gapfill material.

After the optional liner is deposited, n inhibition blocks are performed, with the operations of the first inhibition block (n=1) shown. The first operation is the inhibition plasma, which is a surface treatment. (308) As discussed above, the plasma may include halogen species including anion and radical species such as F⁻, Cl⁻, I⁻, Br⁻, fluorine radicals, etc. Other inhibition plasmas may be used. In some embodiments, the inhibition plasma is generated from non-halogen containing species, including nitrogen-containing, non-halogen-containing species. For example, plasmas generated from molecular nitrogen (N₂), molecular hydrogen (H₂), ammonia (NH₃), amines, diols, diamines, aminoalcohols, thiols, alkyl halides, halides, HF, fluorine-containing species, chlorine-containing species, iodine-containing species, or combinations thereof may be used as inhibition plasmas. In some embodiments, the inhibition plasma treatment is performed at high pressure as described herein.

When the inhibition plasma interacts with material in the feature, the material at the bottom of the feature receives less plasma treatment than material located closer to a top portion of the feature or in field because of geometrical shadowing effects. As a result, deposition at the top of the feature is selective inhibited and deposition in lower portions of the feature proceeds with less inhibition or without being inhibited. In FIG. 3, the next operation in the inhibition block is n2 cycles of ALD fill. (310). The dielectric material is deposited selectively at the bottom of the feature. The inhibition plasma and the n2 cycles of ALD fill together make a growth cycle. This can be repeated n3 times to continue filling the feature with intermittent inhibition operations when the inhibition effect diminishes.

In the example of FIG. 3, the inhibition block ends with a passivation operation. (312). In some embodiments, a passivation operation may not be performed in every inhibition block. Passivation is a surface treatment that removes residual inhibitor and can also densify the deposited film. In some embodiments, a passivation operation comprises exposing the substrate to a passivation plasma. A passivation plasma may be a hydrogen and/or oxygen plasma. In some embodiments, a passivation plasma comprises hydrogen-containing and/or oxygen-containing species co-flowed with an inert gas. In some embodiments, a passivation plasma may include hydrogen species including radicals or ionic species such as H⁺, H⁻, hydrogen radicals, etc., which may be generated from hydrogen-containing species such as H₂. In some embodiments, a passivation plasma may comprise oxygen-containing species including radicals or ionic species such as O₂⁺, O₂⁻, O₃⁻, O, O⁺, O⁻, ionised ozone, and metastable excited oxygen, which may be generated from oxygen-containing species such as 02. The passivation operation may be performed according to various embodiments discussed above.

One or more additional inhibition blocks, including growth cycle and passivation, may be performed for a total of n inhibition blocks. (314). The number of inhibition blocks depends on how much material is used to fill the feature. Inhibition plasma, ALD, and passivation conditions may be changed from inhibition block to inhibition block to fill the feature. For example, an inhibition plasma duration may be 20 seconds until the bottom quarter of the feature is filled (inhibition block 1), then changed to 5 seconds for the middle 50% of the structure (inhibition block 2), etc. Each inhibition block may have a different IED, where process parameters for an inhibition plasma treatment for an inhibition block are changed to target a different IED. Each inhibition block may fill a portion of the feature below an IED of that inhibition block.

When the feature is nearly filled, inhibition may no longer be necessary, and the fill can be completed with n4 cycles of ALD fill. (316). In some embodiments, an optional cap or overburden layer of dielectric may then be deposited. (318). Plasma enhanced chemical vapor deposition (PECVD) may be used at this stage for a fast deposition.

As described above, ALD is used to deposit dielectric material in the feature. ALD is a technique that sequentially deposits thin layers of material. ALD processes use surface-mediated deposition reactions to deposit films on a layer-by-layer basis in cycles. The concept of an ALD “cycle” is relevant to the discussion of various embodiments herein. Generally, a cycle is the minimum set of operations used to perform a surface deposition reaction one time. The result of one cycle is the production of at least a partial silicon-containing film layer on a substrate surface. Typically, an ALD cycle includes operations to deliver and adsorb at least one reactant to the substrate surface, and then react the adsorbed reactant with one or more reactants to form the partial layer of film. The cycle may include certain ancillary operations such as sweeping one of the reactants or byproducts and/or treating the partial film as deposited. Generally, a cycle contains one instance of a unique sequence of operations.

As an example, an ALD cycle may include the following operations: (i) delivery/adsorption of a precursor, (ii) purging of the precursor from the chamber, (iii) delivery of a second reactant and optional plasma ignition, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc.

In one example of an ALD process, a substrate surface that includes a population of surface-active sites is exposed to a gas phase distribution of a first precursor, such as a silicon-containing precursor, in a dose provided to a chamber housing the substrate. Molecules of this first precursor are adsorbed onto the substrate surface, including chemisorbed species and/or physisorbed molecules of the first precursor. When a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen-containing gas or nitrogen-containing gas, is introduced to the chamber so that some of these molecules react with the first precursor adsorbed on the surface. In some processes, the second reactant reacts immediately with the adsorbed first precursor. In other embodiments, the second reactant reacts only if a source of activation such as plasma is applied temporally. The chamber may then be evacuated again to remove unbound second reactant molecules. As described above, in some embodiments the chamber may not be completely evacuated. Additional ALD cycles may be used to build film thickness.

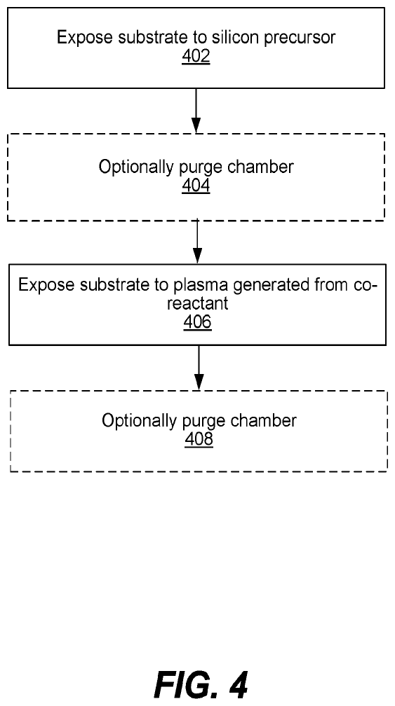

FIG. 4 presents a process flow diagram for a single plasma enhanced ALD cycle that may be implemented as part of operations 304, 310, and/or 316 shown in FIG. 3. In an operation 402, the substrate is exposed to a silicon-containing precursor, to adsorb the precursor onto the surface of the feature. This operation may be self-limiting. In some embodiments, the precursor adsorbs to less than all the active sites on the surface of the feature. In an operation 404, the process chamber is optionally purged to remove any unadsorbed silicon-containing precursors. In an operation 406, the substrate is exposed to a plasma generated from a co-reactant. Examples include O₂ and/or N₂O to form a silicon oxide layer or silicon oxynitride layer, N₂ or NH₃ to form a silicon nitride layer, methane (CH₄) to generate a silicon carbide layer etc. In operation 408, the process chamber is optionally purged to remove byproducts from the reaction between the silicon-containing precursor and the oxidant. Operations 402 through 408 repeated for a number of cycles to deposit the silicon-containing layer to a desired thickness in the feature.

It should be noted that the processes described herein are not limited to a particular reaction mechanism. Thus, the process described with respect to FIG. 4 includes all deposition processes that use sequential exposures to silicon-containing reactants and conversion plasmas, including those that are not strictly self-limiting. The process includes sequences in which one or more gases used to generate a plasma is continuously flowed throughout the process with intermittent plasma ignitions.

In some embodiments, an inhibition plasma treatment may be performed at a pressure of more than about 1 Torr, at least about 10 Torr, at least about 15 Torr, at least about 20 Torr, between about 10 Torr and about 30 Torr, or between about 15 Torr and 30 Torr.

The duration of an inhibition plasma treatment may be between about 0.3 seconds and about 60 seconds, between about 0.3 seconds and about 30 seconds, at least about 0.3 seconds, at least about 1 second, at least about 5 seconds. at least about 10 seconds, at least about 20 seconds, or at least about 30 seconds. Inhibition plasma treatment using a halogen-containing species may generally be for a shorter duration than a non-halogen-containing species, as the halogen-containing species may more effectively passivate the surface compared to non-halogen-containing species.

High pressure inhibition plasma treatment may be used for various aspect ratios and structure depths. In some embodiments, high pressure inhibition plasma treatment may be used for low aspect ratio structures. A low aspect ratio structure may have an aspect ratio between about 3:1 and about 7:1, less than about 10:1, between about 3:1 and about 10:1, between about 3:1 and about 15:1, or less than about 15:1. A low aspect ratio structure may have a depth of at least about 100 nm, at least about 1 μm, at least about 2 μm, or at least about 3 μm.

In some embodiments, IED may be characterized by a percentage, e.g., 30% IED refers to an inhibition effective depth of 30% of the total depth of a feature. Thus, if a feature has a depth of 1 μm, a 30% IED means deposition would be inhibited along the sidewall surface of the feature that is within 300 nm from the top of the feature, with the remaining depth not being inhibited.

In some embodiments the ratio of inhibition species to inert gas may be about 1:5, about 1:10 or between about 1:10 and about 1:20, or between about 1:5 and about 1:5000. Generally, increasing the proportion of the gas flow that is the inhibiting species, such as NF₃, increases the inhibition effect and/or etch component of exposing the substrate to an inhibition plasma. In some embodiments, the flow of non-halogen-containing species, such as N₂, may be between about 10 slm and about 100 slm. In some embodiments, an inert gas may be co-flowed with the species used for inhibition. Inert gases may include helium, argon, xenon, or other gases that are non-reactive with the other species in the gas or surfaces of the substrate. The flow of inert gases, when used, may be between about 3.5 and about 15 slm. In some embodiments, oxygen- or hydrogen-containing species may be co-flowed with the species used for inhibition. If the species used for inhibition includes a nitrogen atom, the nitrogen atom may react with silicon-containing precursors or the silicon film to form silicon nitride. Adding oxygen- or hydrogen-containing species may inhibit conversion of silicon oxide or silicon to silicon nitride, respectively. In some embodiments, co-flows of oxygen- or hydrogen-containing species may be at least about 100 sccm, or between about 0 and about 5 slm.

In various embodiments, the plasma is an in-situ plasma, such that the plasma is formed directly above the substrate surface in the station. Example power per substrate areas for an in-situ plasma are between about 0.2122 W/cm² and about 2.122 W/cm² in some embodiments. For example, the power may range from about 1000 W to about 6000 W for a chamber processing four 300 mm wafers. In some embodiments, the power may be between about 2500 W and about 6000 W for four 300 mm wafers. Plasmas for ALD processes may be generated by applying a radio frequency (RF) field to a gas using two capacitively coupled plates. Ionization of the gas between plates by the RF field ignites the plasma, creating free electrons in the plasma discharge region. These electrons are accelerated by the RF field and may collide with gas phase reactant molecules. Collision of these electrons with reactant molecules may form radical species that participate in the deposition process. It will be appreciated that the RF field may be coupled via any suitable electrodes. Non-limiting examples of electrodes include process gas distribution showerheads and substrate support pedestals. It will be appreciated that plasmas for ALD processes may be formed by one or more suitable methods other than capacitive coupling of an RF field to a gas. In some embodiments, the plasma is a remote plasma, such that second reactant is ignited in a remote plasma generator upstream of the station, then delivered to the station where the substrate is housed.

For depositing silico-containing materials, one or more silicon-containing precursors may be used. In some examples, silicon-containing precursors can include silanes (e.g., SiH₄), polysilanes (H₃Si—(SiH₂)ₙ—SiH₃) where n≥1, organosilanes, halogenated silanes, aminosilanes, alkoxysilanes, and the like. Organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane (H₃Si(NH₂), H₂Si(NH₂)₂, HSi(NH₂)₃ and Si(NH₂)₄, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH₃)₃)₂ (BTBAS), tert-butyl silylcarbamate, SiH(CH₃)—(N(CH₃)₂)₂, SiHCl—(N(CH₃)₂)₂, (Si(CH₃)₂NH)₃, di-isopropylaminosilane (DIPAS), di-sec-butylaminosilane (DSBAS), SiH₂[N(CH₂CH₃)₂]₂ (BDEAS) and the like. A further example of an aminosilane is trisilylamine (N(SiH₃)). In some embodiments, an aminosilane that has two or more amine groups attached to the central Si atom may be used. These may result in less damage than aminosilanes having only a single amine group attached.

Further examples of silicon-containing precursors include trimethylsilane (3MS); ethylsilane; butasilanes; pentasilanes; octasilanes; heptasilane; hexasilane; cyclobutasilane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxydodecasiloxane (OMODDS); tert-butoxydisilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

In some implementations silicon-containing precursors may include siloxanes or amino-group-containing siloxanes. In some embodiments, siloxanes used herein may have a formula of X(R¹)ₐSi—O—Si(R²)_{b}Y, where a and b are integers from 0 to 2, and X and Y independently can be H or NR³R⁴, where each of R1, R2, R3 and R4 is hydrogen, unbranched alkyl, branched alkyl, saturated heterocyclic, unsaturated heterocyclic groups, or combinations thereof. In some embodiments, when at least one X or Y is NR³R⁴, R3 and R4, taken together with the atom to which each are attached, form a saturated heterocyclic compound. In some embodiments, the silicon-containing precursors are pentamethylated amino group containing siloxanes or dimethylated amino group containing siloxanes. Examples of amino group containing siloxanes include: 1-diethylamino 1,1,3,3,3,-pentamethyl disiloxane, 1-diisopropylamino-1,1,3,3,3,-pentamethyl disiloxane, 1 dipropylamino-1,1,3,3,3,-pentamethyl disiloxane, 1-di-n-butylamino-1,1,3,3,3,-pentamethyl disiloxane, 1-di-sec-butylamino-1,1,3,3,3,-pentamethyl disiloxane, 1-N-methylethylamino 1,1,3,3,3,-pentamethyl disiloxane, 1-N-methylpropylamino-1,1,3,3,3,-pentamethyl disiloxane, 1N-methylbutylamino-1,1,3,3,3,-pentamethyl disiloxane, 1-t-butylamino-1,1,3,3,3,-pentamethyl disiloxane, 1-piperidino-1,1,3,3,3,-pentamethyl disiloxane, 1-dimethylamino-1,1-dimethyl disiloxane, 1-diethylamino-1,1-dimethyl disiloxane, 1-diisopropylamino-1,1-dimethyl disiloxane, 1-dipropylamino-1,1-dimethyl disiloxane, 1-di-n-butylamino-1,1-dimethyl disiloxane, 1-di-sec butylamino-1,1-dimethyl disiloxane, 1-N-methylethylamino-1,1-dimethyl disiloxane, 1-N methylpropylamino-1,1-dimethyl disiloxane, 1-N-methylbutylamino-1,1-dimethyl disiloxane, 1 piperidino-1,1-dimethyl disiloxane, 1-t-butylamino-1,1-dimethyl disiloxane, 1-dimethylamino-disiloxane, 1-diethylamino-disiloxane, 1-diisopropylamino-disiloxane, 1-dipropylamino-disiloxane, 1-di-n-butylamino-disiloxane, 1-di-sec-butylamino-disiloxane, 1-N methylethylamino-disiloxane, 1-N-methylpropylamino-disiloxane, 1-N-methylbutylamino-disiloxane, 1-piperidino-disiloxane, 1-t-butylamino disiloxane, and 1-dimethylamino-1,1,5,5,5,-pentamethyl disiloxane.

Where a deposited film includes oxygen, an oxygen-containing species may be used. Examples of oxygen-containing reactants include, but are not limited to, oxygen (O₂), ozone (O₃), nitrous oxide (N₂O), nitric oxide (NO), nitrogen dioxide (NO₂), dinitrogen trioxide (N₂O₃), dinitrogen tetroxide (N₂O₄), dinitrogen pentoxide (N₂O₅), carbon monoxide (CO), carbon dioxide (CO₂), sulfur oxide (SO), sulfur dioxide (SO₂), oxygen-containing hydrocarbons (CₓH_{y}O_{z}), water (H₂O), formaldehyde (CH₂O), carbonyl sulfide (COS), mixtures thereof, etc.

Where a deposited film includes nitrogen, a nitrogen-containing species may be used. A nitrogen-containing reactant contains at least one nitrogen, for example, nitrogen (N₂), ammonia (NH₃), hydrazine (N₂H₄), amines (e.g., amines bearing carbon) such as methylamine (CH₅N), dimethylamine ((CH₃)₂NH), ethylamine (C₂H₅NH₂), isopropylamine (C₃H₉N), t-butylamine (C₄H₁₁N), di-t-butylamine (C₈H₁₉N), cyclopropylamine (C₃H₅NH₂), sec-butylamine (C₄H₁₁N), cyclobutylamine (C₄H₇NH₂), isoamylamine (C₅H₁₃N), 2-methylbutan-2-amine (C₅H₁₃N), trimethylamine (C₃H₉N), diisopropylamine (C₆H₁₅N), diethylisopropylamine (C₇H₁₇N), di-t-butylhydrazine (C₈H₂₀N₂), as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants. Other examples include NₓO_{y} compounds such as nitrous oxide (N₂O), nitric oxide (NO), nitrogen dioxide (NO₂), dinitrogen trioxide (N₂O₃), dinitrogen tetroxide (N₂O₄) and/or dinitrogen pentoxide (N₂O₅).

### Apparatus

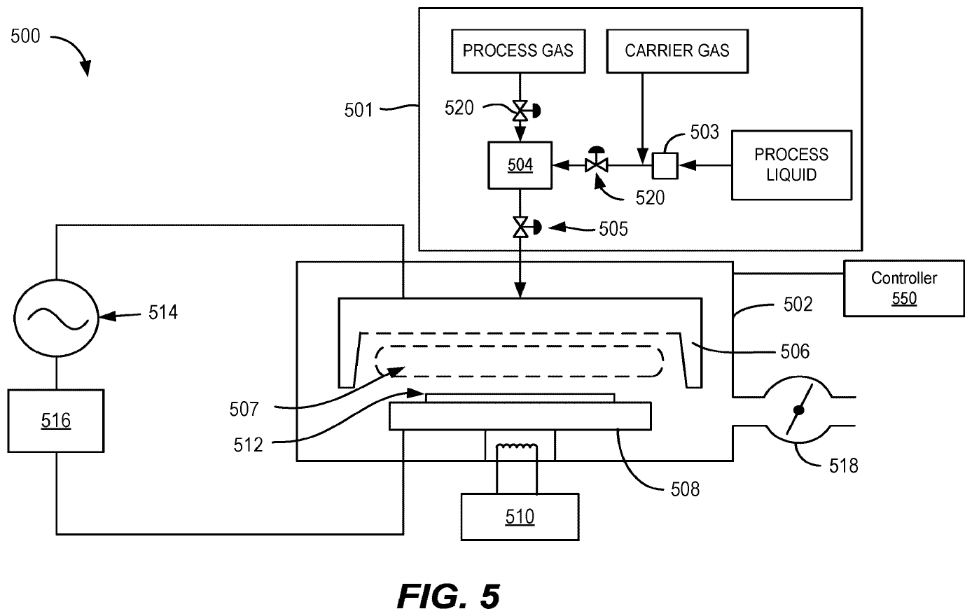

FIG. 5 schematically shows an embodiment of a process station 500 that may be used to deposit material using atomic layer deposition (ALD) and/or chemical vapor deposition (CVD), either of which may be plasma enhanced. For simplicity, the process station 500 is depicted as a standalone process station having a process chamber body 502 for maintaining a low-pressure environment. However, it will be appreciated that a plurality of process stations 500 may be included in a common process tool environment. Further, it will be appreciated that, in some embodiments, one or more hardware parameters of process station 500, including those discussed in detail below, may be adjusted programmatically by one or more computer controllers 550.

Process station 500 fluidly communicates with reactant delivery system 501 for delivering process gases to a distribution showerhead 506. Reactant delivery system 501 includes a mixing vessel 504 for blending and/or conditioning process gases for delivery to showerhead 506. One or more mixing vessel inlet valves 520 may control introduction of process gases to mixing vessel 504. Similarly, a showerhead inlet valve 505 may control introduction of process gasses to the showerhead 506. In some embodiments, an inhibitor or other gas may be directly delivered to the chamber body 502. One or more mixing vessel inlet valves 520 may control introduction of process gases to mixing vessel 504. These valves may be controlled depending on whether a process gas, inhibition gas, or carrier gas may be turned on during various operations. In some embodiments, an inhibition gas may be generated by using an inhibition liquid and vaporizing using a heated vaporizer.

As an example, the embodiment of FIG. 5 includes a vaporization point 503 for vaporizing liquid reactant to be supplied to mixing vessel 504. In some embodiments, vaporization point 503 may be a heated vaporizer. The reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve sweeping and/or evacuating the delivery piping to remove residual reactant. However, sweeping the delivery piping may increase process station cycle time, degrading process station throughput. Thus, in some embodiments, delivery piping downstream of vaporization point 503 may be heat traced. In some examples, mixing vessel 504 may also be heat traced. In one non-limiting example, piping downstream of vaporization point 503 has an increasing temperature profile extending from approximately 100 °C to approximately 150 °C at mixing vessel 504.

In some embodiments, reactant liquid may be vaporized at a liquid injector. For example, a liquid injector may inject pulses of a liquid reactant into a carrier gas stream upstream of the mixing vessel. In one scenario, a liquid injector may vaporize reactant by flashing the liquid from a higher pressure to a lower pressure. In another scenario, a liquid injector may atomize the liquid into dispersed microdroplets that are subsequently vaporized in a heated delivery pipe. It will be appreciated that smaller droplets may vaporize faster than larger droplets, reducing a delay between liquid injection and complete vaporization. Faster vaporization may reduce a length of piping downstream from vaporization point 503. In one scenario, a liquid injector may be mounted directly to mixing vessel 504. In another scenario, a liquid injector may be mounted directly to showerhead 506.

In some embodiments, a liquid flow controller (LFC) upstream of vaporization point 503 may be provided for controlling a mass flow of liquid for vaporization and delivery to process station 500. For example, the liquid flow controller may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, the LFC may be dynamically switched from a feedback control mode to a direct control mode by disabling a sense tube of the LFC and the PID controller.

Showerhead 506 distributes process gases toward substrate 512. In the embodiment shown in FIG. 5, substrate 512 is located beneath showerhead 506, and is shown resting on a pedestal 508. It will be appreciated that showerhead 506 may have any suitable shape, and may have any suitable number and arrangement of ports for distributing processes gases to substrate 512.

In some embodiments, a microvolume 507 is located beneath showerhead 506. Performing an ALD and/or CVD process in a microvolume rather than in the entire volume of a process station may reduce reactant exposure and sweep times, may reduce times for altering process conditions (e.g., pressure, temperature, etc.), may limit an exposure of process station robotics to process gases, etc. Example microvolume sizes include, but are not limited to, volumes between 0.1 liter and 2 liters. This microvolume also impacts productivity throughput. While deposition rate per cycle drops, the cycle time also simultaneously reduces. In certain cases, the effect of the latter is dramatic enough to improve overall throughput of the module for a given target thickness of film.

In some embodiments, pedestal 508 may be raised or lowered to expose substrate 512 to microvolume 507 and/or to vary a volume of microvolume 507. For example, in a substrate transfer phase, pedestal 508 may be lowered to allow substrate 512 to be loaded onto pedestal 508. During a deposition process phase, pedestal 508 may be raised to position substrate 512 within microvolume 507. In some embodiments, microvolume 507 may completely enclose substrate 512 as well as a portion of pedestal 508 to create a region of high flow impedance during a deposition process.

Optionally, pedestal 508 may be lowered and/or raised during portions the deposition process to modulate process pressure, reactant concentration, etc., within microvolume 507. In one scenario where process chamber body 502 remains at a base pressure during the deposition process, lowering pedestal 508 may allow microvolume 507 to be evacuated. Example ratios of microvolume to process chamber volume include, but are not limited to, volume ratios between 1:500 and 1:10. It will be appreciated that, in some embodiments, pedestal height may be adjusted programmatically by a suitable computer controller.

In another scenario, adjusting a height of pedestal 508 may allow a plasma density to be varied during plasma activation and/or treatment cycles included in the deposition process. At the conclusion of the deposition process phase, pedestal 508 may be lowered during another substrate transfer phase to allow removal of substrate 512 from pedestal 508.

While the example microvolume variations described herein refer to a height-adjustable pedestal, it will be appreciated that, in some embodiments, a position of showerhead 506 may be adjusted relative to pedestal 508 to vary a volume of microvolume 507. Further, it will be appreciated that a vertical position of pedestal 508 and/or showerhead 506 may be varied by any suitable mechanism within the scope of the present disclosure. In some embodiments, pedestal 508 may include a rotational axis for rotating an orientation of substrate 512. It will be appreciated that, in some embodiments, one or more of these example adjustments may be performed programmatically by one or more suitable computer controllers.

Returning to the embodiment shown in FIG. 5, showerhead 506 and pedestal 508 electrically communicate with RF power supply 514 and matching network 516 for powering a plasma. In some embodiments, the plasma energy may be controlled by controlling one or more of a process station pressure, a gas concentration, an RF source power, an RF source frequency, and a plasma power pulse timing. For example, RF power supply 514 and matching network 516 may be operated at any suitable power to form a plasma having a desired composition of radical species. Examples of suitable powers are included above. Likewise, RF power supply 514 may provide RF power of any suitable frequency. In some embodiments, RF power supply 514 may be configured to control high- and low-frequency RF power sources independently of one another. Example low-frequency RF frequencies may include, but are not limited to, frequencies between 50 kHz and 500 kHz. Example high-frequency RF frequencies may include, but are not limited to, frequencies between 1.8 MHz and 2.45 GHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, the plasma may be controlled via input/output control (IOC) sequencing instructions. In one example, the instructions for setting plasma conditions for a plasma process phase may be included in a corresponding plasma activation recipe phase of a deposition process recipe. In some cases, process recipe phases may be sequentially arranged, so that all instructions for a deposition process phase are executed concurrently with that process phase. In some embodiments, instructions for setting one or more plasma parameters may be included in a recipe phase preceding a plasma process phase. For example, a first recipe phase may include instructions for setting a flow rate of an inert and/or a reactant gas, instructions for setting a plasma generator to a power set point, and time delay instructions for the first recipe phase. A second, subsequent recipe phase may include instructions for enabling the plasma generator and time delay instructions for the second recipe phase. A third recipe phase may include instructions for disabling the plasma generator and time delay instructions for the third recipe phase. It will be appreciated that these recipe phases may be further subdivided and/or iterated in any suitable way within the scope of the present disclosure.

In some deposition processes, plasma strikes last on the order of a few seconds or more in duration. In certain implementations, much shorter plasma strikes may be used. These may be on the order of 10 ms to 1 second, typically, about 20 to 80 ms, with 50 ms being a specific example. Such very short RF plasma strikes require extremely quick stabilization of the plasma. To accomplish this, the plasma generator may be configured such that the impedance match is set preset to a particular voltage, while the frequency is allowed to float. Conventionally, high-frequency plasmas are generated at an RF frequency at about 13.56 MHz. In various embodiments disclosed herein, the frequency is allowed to float to a value that is different from this standard value. By permitting the frequency to float while fixing the impedance match to a predetermined voltage, the plasma can stabilize much more quickly, a result which may be important when using the very short plasma strikes associated with some types of deposition cycles.

In some embodiments, pedestal 508 may be temperature controlled via heater 510. Further, in some embodiments, pressure control for deposition process station 500 may be provided by butterfly valve 518. As shown in the embodiment of FIG. 5, butterfly valve 518 throttles a vacuum provided by a downstream vacuum pump (not shown). However, in some embodiments, pressure control of process station 500 may also be adjusted by varying a flow rate of one or more gases introduced to process station 500.

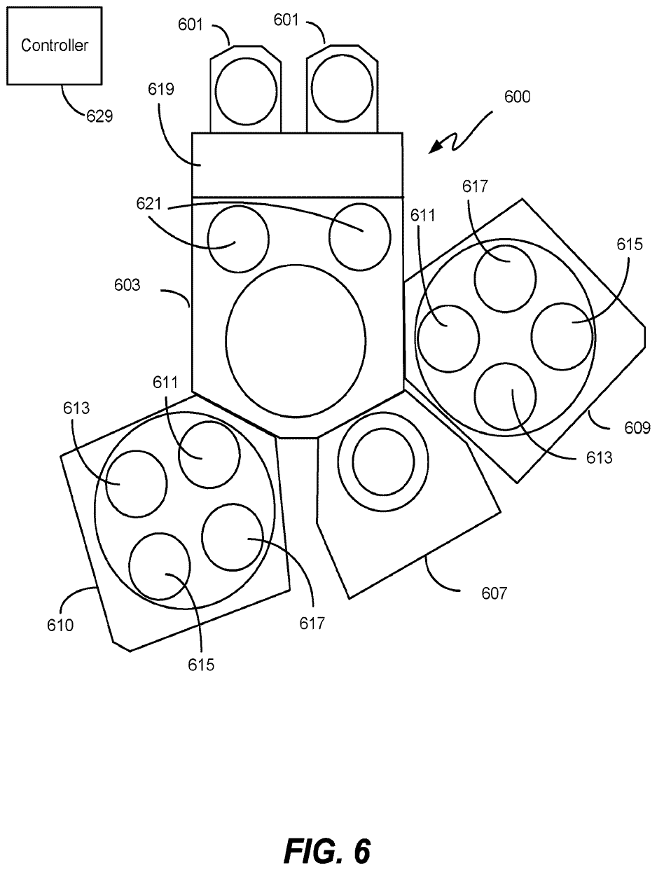

FIG. 6 is a block diagram of a processing system suitable for conducting thin film deposition processes in accordance with certain embodiments. The system 600 includes a transfer module 603. The transfer module 603 provides a clean, pressurized environment to minimize risk of contamination of substrates being processed as they are moved between various reactor modules. Mounted on the transfer module 603 are two multi-station reactors 609 and 610, each capable of performing atomic layer deposition (ALD) and/or chemical vapor deposition (CVD) according to certain embodiments. Reactors 609 and 610 may include multiple stations 611, 613, 615, and 617 that may sequentially or non-sequentially perform operations in accordance with disclosed embodiments. The stations may include a heated pedestal or substrate support, one or more gas inlets or showerhead or dispersion plate.

Also mounted on the transfer module 603 may be one or more single or multi-station modules 607 capable of performing plasma or chemical (non-plasma) pre-cleans, or any other processes described in relation to the disclosed methods. The module 607 may in some cases be used for various treatments to, for example, prepare a substrate for a deposition process. The module 607 may also be designed/configured to perform various other processes such as etching or polishing. The system 600 also includes one or more wafer source modules 601, where wafers are stored before and after processing. An atmospheric robot (not shown) in the atmospheric transfer chamber 619 may first remove wafers from the source modules 601 to loadlocks 621. A wafer transfer device (generally a robot arm unit) in the transfer module 603 moves the wafers from loadlocks 621 to and among the modules mounted on the transfer module 603.

In various embodiments, a system controller 629 is employed to control process conditions during deposition. The controller 629 will typically include one or more memory devices and one or more processors. A processor may include a CPU or computer, analog and/or digital input/output connections, stepper motor controller boards, etc. The one or more memories may comprise computer-executable code that may be executed by the one or more processors.

The controller 629 may control all of the activities of the deposition apparatus. The system controller 629 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 629 may be employed in some embodiments.

Typically there will be a user interface associated with the controller 629. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the inhibition species flow, hydrogen flow, oxygen flow, and silicon-containing precursor flow, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 629. The signals for controlling the process are output on the analog and digital output connections of the deposition apparatus 600.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller, such as controller 550 or 629, is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 629, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

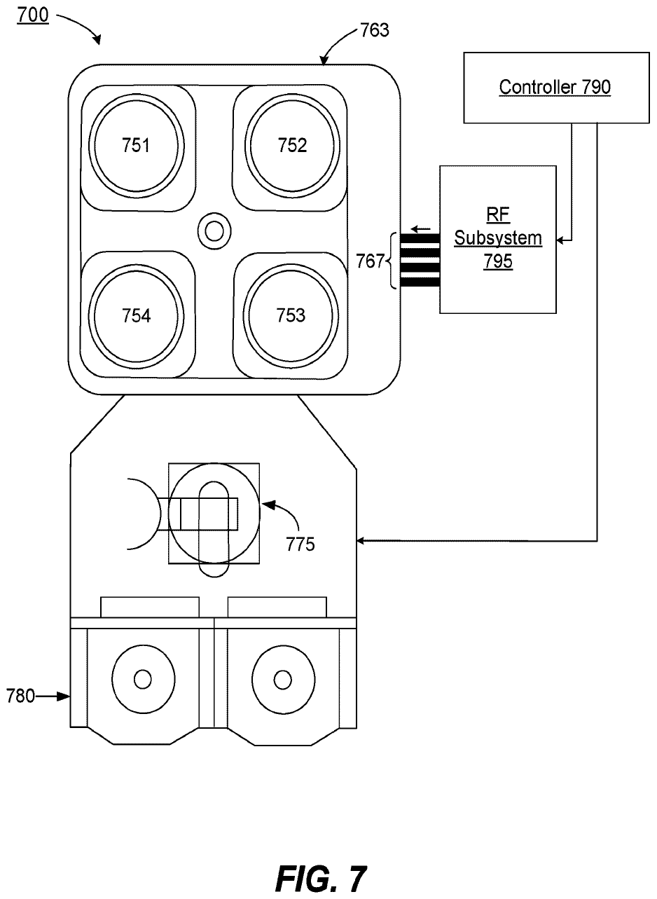

It may be appreciated that a plurality of process stations may be included in a multi-station processing tool environment, such as shown in FIG. 7, which depicts a schematic view of an embodiment of a multi-station processing tool. Processing apparatus 700 employs an integrated circuit fabrication chamber 763 that includes multiple fabrication process stations, each of which may be used to perform processing operations on a substrate held in a wafer holder, such as a pedestal, at a particular process station. In the embodiment of FIG. 7, the integrated circuit fabrication chamber 763 is shown having four process stations 751, 752, 753, and 754. Other similar multi-station processing apparatuses may have more or fewer process stations depending on the implementation and, for example, a desired level of parallel wafer processing, size/space constraints, cost constraints, etc. Also shown in FIG. 7 is substrate handler robot 775, which may operate under the control of system controller 790, configured to move substrates from a wafer cassette (not shown in FIG. 7) from loading port 780 and into integrated circuit fabrication chamber 763, and onto one of process stations 751, 752, 753, and 754.

FIG. 7 also depicts an embodiment of a system controller 790 employed to control process conditions and hardware states of processing apparatus 700. System controller 790 may include one or more memory devices, one or more mass storage devices, and one or more processors, as described herein.

RF subsystem 795 may generate and convey RF power to integrated circuit fabrication chamber 763 via radio frequency input ports 767. In particular embodiments, integrated circuit fabrication chamber 763 may comprise input ports in addition to radio frequency input ports 767 (additional input ports not shown in FIG. 7). Accordingly, integrated circuit fabrication chamber 763 may utilize 8 RF input ports. In particular embodiments, process stations 751-754 of integrated circuit fabrication chamber 763 may each utilize first and second input ports in which a first input port may convey a signal having a first frequency and in which a second input port may convey a signal having a second frequency. Use of dual frequencies may bring about enhanced plasma characteristics.

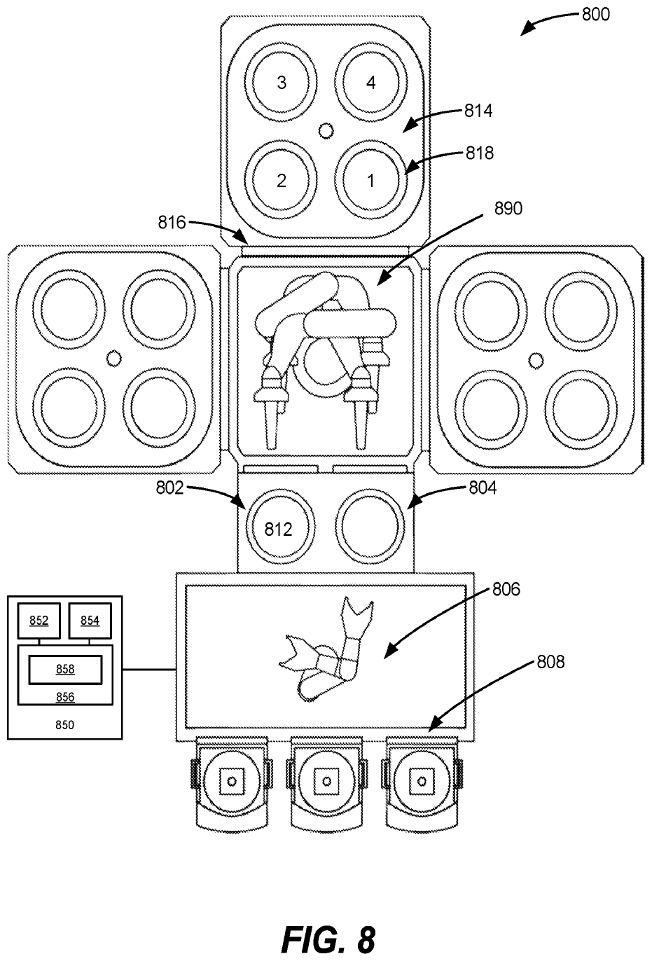

As described above, one or more process stations may be included in a multi-station processing tool. FIG. 8 shows a schematic view of an embodiment of a multi-station processing tool 800 with an inbound load lock 802 and an outbound load lock 804, either or both of which may comprise a remote plasma source. A robot 806, at atmospheric pressure, is configured to move substrates or wafers from a cassette loaded through a pod 808 into inbound load lock 802 via an atmospheric port. A substrate is placed by the robot 806 on a pedestal 812 in the inbound load lock 802, the atmospheric port is closed, and the load lock is pumped down. Where the inbound load lock 802 comprises a remote plasma source, the substrate may be exposed to a remote plasma treatment in the load lock prior to being introduced into a processing chamber 814. Further, the substrate also may be heated in the inbound load lock 802 as well, for example, to remove moisture and adsorbed gases. Next, a chamber transport port 816 to processing chamber 814 is opened, and another robot 890 places the substrate into the reactor on a pedestal of a first station shown in the reactor for processing. While the embodiment depicted in FIG. 9 includes load locks, it will be appreciated that, in some embodiments, direct entry of a substrate into a process station may be provided. In various embodiments, the soak gas is introduced to the station when the substrate is placed by the robot 806 on the pedestal 812.

The depicted processing chamber 814 includes four process stations, numbered from 1 to 4 in the embodiment shown in FIG. 8. Each station has a heated pedestal (shown at 818 for station 1), and gas line inlets. It will be appreciated that in some embodiments, each process station may have different or multiple purposes. For example, in some embodiments, a process station may be switchable between an inhibition plasma, passivation plasma, ALD and/or PEALD process mode. Additionally or alternatively, in some embodiments, processing chamber 814 may include one or more matched pairs of ALD and plasma-enhanced ALD process stations. While the depicted processing chamber 814 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 8 depicts an embodiment of a wafer handling system 890 for transferring substrates within processing chamber 814. In some embodiments, wafer handling system 890 may transfer substrates between various process stations and/or between a process station and a load lock. It will be appreciated that any suitable wafer handling system may be employed. Non-limiting examples include wafer carousels and wafer handling robots. FIG. 8 also depicts an embodiment of a system controller 850 employed to control process conditions and hardware states of process tool 800. System controller 850 may include one or more memory devices 856, one or more mass storage devices 854, and one or more processors 852. Processor 852 may include a CPU or computer, analog and/or digital input/output connections, stepper motor controller boards, etc. In some embodiments, system controller 850 includes machine-readable instructions for performing operations such as those described herein.

In some embodiments, system controller 850 controls the activities of process tool 800. System controller 850 executes system control software 858 stored in mass storage device 854, loaded into memory device 856, and executed on processor 852. Alternatively, the control logic may be hard coded in the system controller 850. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 858 may include instructions for controlling the timing, mixture of gases, amount of gas flow, chamber and/or station pressure, chamber and/or station temperature, substrate temperature, target power levels, RF power levels, substrate pedestal, chuck and/or susceptor position, and other parameters of a particular process performed by process tool 800. System control software 858 may be configured in any suitable way. For example, various process tool component subroutines or control objects may be written to control operation of the process tool components used to carry out various process tool processes. System control software 858 may be coded in any suitable computer readable programming language.

### CONCLUSION

Although the foregoing embodiments have been described in some detail for purposes of clarity of understanding, it will be apparent that certain changes and modifications may be practiced within the scope of the appended claims. Embodiments disclosed herein may be practiced without some or all of these specific details. In other instances, well-known process operations have not been described in detail to not unnecessarily obscure the disclosed embodiments. Further, while the disclosed embodiments will be described in conjunction with specific embodiments, it will be understood that the specific embodiments are not intended to limit the disclosed embodiments. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method, comprising:
providing a substrate in a process chamber, the substrate having one or more structures, each structure comprising a gap;
performing a first set of cycles of:
(a) exposing the substrate to an inhibition plasma to inhibit deposition on a portion of each gap, wherein the inhibition plasma comprises fluorine-containing species, and
(b) after (a), depositing a dielectric material in each gap, and
after performing the first set of cycles, exposing the substrate to a passivation plasma to reduce a concentration of fluorine in the dielectric material, wherein the concentration of fluorine after exposing the substrate to the passivation plasma is less than about 10²⁰ atoms/cm³.

2. The method of claim 1, wherein the concentration of fluorine in the dielectric material is measured from a bulk portion of the dielectric material.

3. The method of claim 1, wherein the concentration of fluorine in the dielectric material is an average concentration at a depth from a surface of the substrate of at least 5 nm.

4. The method of claim 1, wherein the concentration of fluorine after exposing the substrate to the passivation plasma is less than about 10¹⁹ atoms/cm³.

5. The method of claim 1, wherein a duration of the passivation plasma is at least about 80 seconds.

6. The method of claim 1, wherein the passivation plasma has a high frequency (HF) power of at least about 5000 W.

7. The method of claim 1, wherein the passivation plasma has a low frequency (LF) power between about 0 and about 2000 W.

8. The method of claim 1, wherein the dielectric material has a wet etch rate less than 1 A/s.

9. The method of claim 1, wherein the inhibition plasma comprises a nitrogen-containing species.

10. The method of claim 9, wherein the passivation plasma reduces the concentration of nitrogen in the dielectric material.

11. The method of claim 1, wherein the dielectric material comprises silicon-containing material.

12. The method of claim 11, wherein the silicon-containing material comprises silicon oxide.

13. The method of claim 1, wherein the passivation plasma comprises an oxygen-containing species.

14. The method of claim 1, wherein the passivation plasma comprises a hydrogen-containing species.

15. The method of claim 1, wherein the passivation plasma comprises an oxygen-containing species and a hydrogen-containing species.

16. A system, comprising:
a process chamber; and
one or more processors and one or more memories, the one or more processors and the one or more memories comprising computer-executable instructions for:
providing a substrate in the process chamber, the substrate having one or more structures, each structure comprising a gap;
performing a first set of cycles of:
(a) exposing the substrate to an inhibition plasma to inhibit deposition on a portion of each gap, wherein the inhibition plasma comprises fluorine-containing species, and
(b) after (a), depositing a dielectric material in each gap, and
after performing the first set of cycles, exposing the substrate to a passivation plasma,
wherein a duration of the passivation plasma is at least about 80 seconds and a high frequency (HF) power of the passivation plasma is at least about 5000 W.
